(19) United States
(12) Patent Application Publication
(10) Pub. No.: US 2007/0215201 A1
(43) Pub. Date: Sep. 20, 2007

(54) Photovoltaic cell with integral light transmitting waveguide in a ceramic sleeve

(76) Inventor: Lawrence Curtin, Hutchinson Island, FL (US)

Correspondence Address: HAYWORTH, CHANEY & THOMAS, P.A., 202 N. HARBOR CITY BLVD., SUITE 300, MELBOURNE, FL, 32935, US

(21) Appl. No.: 11/636,324

(22) Filed: Dec. 8, 2006

Related U.S. Application Data
(60) Provisional application No. 60/783,638, filed on Mar. 17, 2006.

(51) Int. Cl. H01L 31/00

(52) U.S. Cl. 136/252

(57) ABSTRACT

Photovoltaic cells are semiconductor devices known in the art to produce an electric current in the presence of light when placed in a closed electric circuit. The amount of electric current generated is typically a function of the area of the cell exposed to light. The invention is an improved photovoltaic cell comprised of multiple layers of semiconductor material forming N-P junctions with interdispersed light transmitting particles in a ceramic sleeve. The light transmitting particles act as waveguides enabling light to be transmitted through multiple layers of semiconductor material to lower N-P layers, where they are absorbed, generating an electric current. Photovoltaic cells of a plurality of layers and in varying dimensions may be fabricated, yielding a variety of form factors available to the photovoltaic cell designer and enabling photovoltaic cell use in numerous applications. The present invention is also directed to a method for fabricating such photovoltaic cells.

### CROSS REFERENCE TO RELATED APPLICATIONS

This United States utility application is based upon U.S. provisional application Ser. No. 60/783,638, and priority to this provisional application is claimed and the entire contents of 60/783,638 are hereby incorporated by reference.

### STATEMENT REGARDING FEDERALLY SPONSORED RESEARCH OR DEVELOPMENT

Not Applicable.

### INCORPORATION-BY-REFERENCE OF MATERIAL SUBMITTED ON A COMPACT DISK

Not Applicable.

### BACKGROUND OF THE INVENTION

1. Field of the Invention

The invention relates to the field of photovoltaic cells used in the generation of electric current when such cells are placed in the presence of light.

2. Background Art

Photovoltaic cells capable of converting light into electrical energy have been commonly used for decades. Photovoltaic devices have the distinct advantage of supplying electric current without the need for separate sources of power such as electrical generators or batteries. These devices are therefore extremely beneficial for use in locations where electrical generators or batteries are unavailable or are too expensive to economically be used. Accordingly, a great deal of research has been conducted with the goal of increasing the efficiency and reducing the cost of photovoltaic cells. Semiconductors materials are materials which exhibit the characteristic of change in charge carrier mobility when exposed to an external excitation such as an electromotive force, heat, pressure, or electromagnetic radiation. Semiconductors are typically categorized into either N-type or P-type semiconductors. N-type and P-type semiconductors are typically brought together into direct physical and electrical contact to form P-N or N-P junctions which are utilized in integrated circuits in a variety of applications. Photovoltaic junctions are P-N or N-P semiconductor junctions typically comprised of semiconductor materials forming separate N and P layers which are brought together into close physical and electrical contact to form a P-N or N-P semiconductor junction, utilizing semiconductor materials which exhibit a change in charge carrier mobility in the presence of light. Photovoltaic cells are typically comprised of photovoltaic junctions housed in a manner such that light incident upon the cell creates an electric current which is made available to the user via electrical contacts such as wires or conductive pads. The amount of electric current generated by a solar cell is typically a function of the intensity of the light incident upon the photovoltaic cell, the types of semiconductors employed, and the area of P-N or N-P junction exposed to the light.

One specific application of such photovoltaic cells is the solar cell. The semiconductor materials in an earth-based solar cell are selected to maximize the efficiency of charge carrier generation and mobility when the solar cell is placed in the presence of the specific frequencies of light generated by the sun and filtered through Earth's atmosphere. Other applications of solar cells for use in spacecraft are comprised of semiconductor materials which exhibit optimum charge carrier generation when exposed to an electromagnetic spectrum that is not filtered through earth's atmosphere. Other specific applications of photovoltaic cell technology utilize semiconductor materials specifically selected for use in applications in which they will be exposed to specific wavelengths of light energy, for instance in applications utilizing the infrared spectrum where such spectrum is desired. This disclosure is not limited to solar cells only; the light transmitting semiconductor elements and the photovoltaic cells described in this disclosure are suitable and intended for use in any application requiring the application of photovoltaic cells. Likewise, the method of fabrication of light transmitting semiconductor elements and the method of fabrication of photovoltaic cells comprised of light transmitting semiconductors described herein are not limited to solar cells but are suitable and intended for use in any application requiring the application of photovoltaic cells. It is a natural extension of the invention that it may be used for any spectrum of light from the infrared through the ultraviolet spectrum, and thus the invention is not limited to visible light, nor is it limited to the specific spectrum which characterizes solar light energy.

The voltage of a solar cell is dependent upon the materials used and the amount of junctions. The amount of electric current generated by a photovoltaic cell is a function of the area of the semiconductor junction exposed to light energy. Because of this direct relationship between the area of the semiconductor junction exposed to light energy to the amount of electric current generated, it is generally desired that photovoltaic cells be of the maximum area possible for a given application in order to generate the greatest amount of electric current for the user. However, specific applications may have a very limited amount of area available for a photovoltaic cell, such that the present photovoltaic cell technology may not be adaptable for use if the area required to generate a given electric current for a specific application is not available to the solar cell designer. This drawback limits the number of applications otherwise suitable for photovoltaic cell use.

Improvements upon the basic photovoltaic cell are common. For instance, U.S. Pat. No. 6,940,009 B2 to Alvarez (2005) discloses a solar cell which claims the addition of mercury and silver nitrate to the semiconductor materials making up the cell, which is usually silicon found in different crystalline states. It is claimed in this patent that the addition of these materials allows the solar cell to absorb certain amounts of energy which is later released into the solar cell, allowing a generation of electric energy for a longer part of the day than would normally be the case. Multi-junction solar cells have also been devised. For instance, U.S. Pat. No. 6,951,819 B2 (2005) to Iles et al. discloses a multi-junction solar cell with features that enable the matching of the band gap of the various layers making up the solar cell utilizing a specific method of epitaxial growth of semiconductor material. An improvement in solar cell efficiency due to better lattice matching is claimed. Other forms of solar cells have been proposed, including polycrystalline thin-film cells. Japanese patent number JP1110776 to Mutsuyuki (publication date 1989) claims a method of fabricating a polycrystalline thin film solar cell that utilizes low temperatures. The claimed advantages of this patent are ease of manufacture and low cost.

Photovoltaic cells generally, and solar cells specifically, are often desired in applications in remote geographical areas in countries which do not have an electric power distribution system to support remote villages or towns. Such countries often lack the financial resources to employ the latest photovoltaic cell technology in these remote regions due to the high cost of such technology, with the result that these remote regions often lack any type of electric power generation whatsoever. It is an aspect of the present invention to provide a method for producing photovoltaic cells that require less total surface area than conventional cells.

### BRIEF SUMMARY OF THE INVENTION

The scope of the present invention includes a photovoltaic cell comprising a first semiconductor layer, the first layer comprising N type semiconductor material having a top surface and a bottom surface, wherein light transmitting particles are interdispersed within the N type semiconductor material; and a second semiconductor layer, the second layer comprising P type semiconductor material having a top surface and a bottom surface, wherein light transmitting particles are interdispersed within the P type semiconductor material, the top surface of the second layer being in direct physical and electrical contact with the bottom surface of the first layer to form an N-P junction.

The present invention functions to overcome the drawbacks associated with the large area required for certain solar cell applications by utilizing a solar cell which is designed and packaged such as to enable light energy to penetrate beyond a single P-N or N-P junction to a plurality of junctions below, creating a photovoltaic current in each successive P-N or N-P junction and to substitute expensive vacuum chambers with a ceramic sleeve where powders are melted into thin film layers. The photovoltaic cell of the present invention thus generates an electric current requiring less surface area to be exposed to the incident light, by utilizing interdispersed light transmitting particles to act as waveguides for the purpose of transmitting light to the photovoltaic junctions below the first junction. This result is achieved in the present invention by including light transmitting elements within the semiconductor materials of the photovoltaic cell such that a portion of the light incident upon a surface of the photovoltaic cell passes through the semiconductor material of the first layer to reach successive P-N or N-P junctions below the top P-N or N-P junction. The inclusion of light transmitting elements in the semiconductor material in each layer enables the lower layers of multi-layer photovoltaic cells to receive light, resulting in an increase in the electric current generated in the lower P-N or N-P semiconductor junctions. The light transmitting elements act as wave guides to allow the transmission of light to the underneath junctions of multi-junction photovoltaic cells. Multi-layer photovoltaic cells can thus be fabricated to meet the electric current generation requirements of a variety of applications that do not have sufficient surface area to allow the use of a conventional single layer photovoltaic cell, and which are thus not typically able to benefit from conventional photovoltaic cell use.

It is a further aspect of the present invention that any light transmitting material may be used, with the limitation that the light transmitting material is able to withstand the temperatures of the fabrication process. The temperature of the fabrication process is dependent upon the semiconductor materials selected for a specific photovoltaic cell application; therefore the semiconductor material and light transmitting material are optimally selected for a specific application such that the light transmitting material exhibits a melting temperature that is higher than the semiconductor transition temperature. It is possible that the light transmitting material may be selected to have a melting temperature lower than the transition temperature of the semiconductor used in a specific application, but such a selection does not achieve optimal results.

The scope of the present invention also includes a method for fabricating multi-layer photovoltaic cells with integral light transmitting material that acts as light waveguides. This method is comprised of reducing the light transmitting materials to a powder form, typically through grinding the light transmitting material to a size of 5 micrometers to 150 micrometers followed by further reducing the particle size to 400 nanometers to 800 nanometers, but optimally 700 nanometers, by wet ball milling; reducing a bulk P-type semiconductor material to a powder form, typically through grinding the material to a size of 5 micrometers to 150 micrometers followed by further reducing the particle size to 400 nanometers to 800 nanometers, but optimally 700 nanometers, by wet ball milling; reducing a bulk N-type semiconductor material to a powder form by first grinding the material to reduce it to particles between 5 micrometers and 150 micrometers in size followed by ball milling to further reduce the particles to between 400 nanometers and 800 hundred nanometers in size, but optimally 700 nanometers; mixing the light transmitting material powder into both the P-type and N-type semiconductor powder, respectively, in equal parts, or larger or smaller by volume; applying alternate layers of the mixed N-type and mixed P-type light transmitting semiconductor materials in successive layers to form a plurality of N-P junctions comprised of alternating layers of N-type and P-type semiconductor powder, each layer mixed with light transmitting materials. A radio frequency may be applied after each layer of N-type or P-type semiconductor powder is deposited, wherein the radio frequency melts the newly deposited layer into a film of between 500 to 600 nanometers. A further embodiment of the above method is further comprised of the step of capturing the alternating layers of N-type and P-type semiconductor powder mixed with light transmitting materials in an enclosure, the enclosure comprising a non-conductive sleeve, the sleeve preferably being ceramic; a conductive bottom element; a top conductive ring element; and a optically transmissive lens element, such as a collimating lens, that is chemically bonded to a top surface of the ring element.

The present invention achieves a significant reduction in the surface area of the photovoltaic cell required to generate a specific amount of electric current in a given application. An improvement in the art of photovoltaic cells is achieved by the present invention in that multi-layer photovoltaic cells can be fabricated to meet the specific form factors required in applications in which the available surface is insufficient for traditional photovoltaic cells, the improvement arising from the ability of the present invention to achieve the generation of electrical current from the lower N-P junctions of a stacked multi-layer photovoltaic cell due the transmission of light through each semiconductor layer to the lower semiconductor layers. As a result, photovoltaic cells may be produced which exhibit greater current-generating capacity for a given surface area of exposure to the incident light.

It is a further aspect of the present invention to enable the use of photovoltaic cells in applications which formerly did not allow such use due to limited available surface area, or due to the high cost of photovoltaic cell technology. For instance, the large surface area of conventional solar cells has made it very difficult historically to install large solar arrays in remote locations due to the cost of production, shipping, installation, and maintenance. Such large area photovoltaic arrays also present challenges in the ability of the large array to survive high winds and other environmental structural loads, such as those loads created by rain or snow. The present invention enables the packaging of photovoltaic cells into any desired physical shape with a reduced overall surface area, such as cubes or elongated tubular structures, which may be designed to fit within very specific size and shape constraints. The difficulty of shipping, storing, deploying, and securing large solar arrays with a large surface area is eliminated or greatly reduced by the present invention.

### BRIEF DESCRIPTION OF THE DRAWINGS

FIG. 1 is a schematic cross section illustration of the composition of a single light transmitting semiconductor layer, which includes the semiconductor particles and light transmitting particles brought together in close proximity.

FIG. 2 is a schematic cross section illustration of a single-junction photovoltaic cell in which a layer of light transmitting N-type semiconductor material is brought together into physical contact with a single layer of light transmitting P-type semiconductor material to form a single P-N junction.

FIG. 3 is a schematic cross section illustration of a multi-layer photovoltaic cell in which multiple layers of light transmitting semiconductor materials are brought together into physical contact to form multiple N-P junctions.

FIG. 4 is a schematic cross section illustration of a photovoltaic cell comprised of light transmitting semiconductor layers as disclosed herein, said photovoltaic cell being housed in an enclosure facilitating actual use of the cell.

FIG. 5 is schematic cross section illustration of a portion of the photovoltaic cell of FIG. 4.

FIG. 6 is a process flow diagram of a method for interdispersing light transmitting wave guide material in the semiconductor layers of single junction photovoltaic cells.

### DETAILED DESCRIPTION OF THE INVENTION

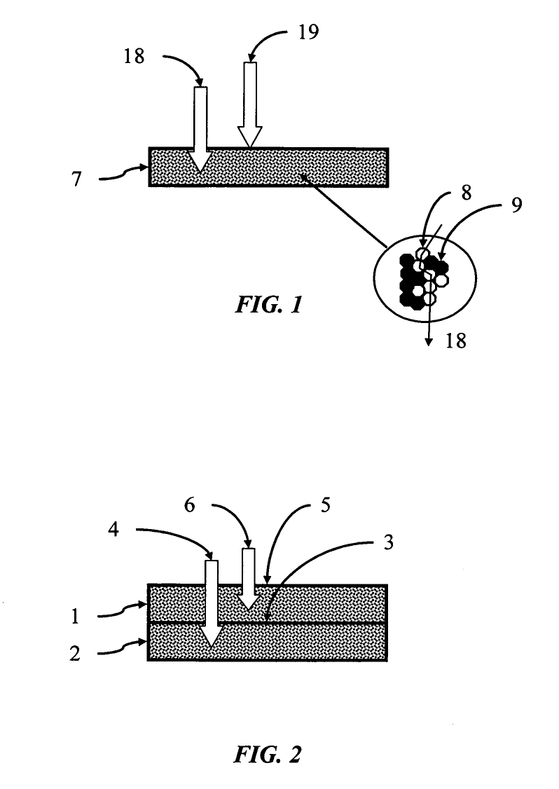

FIG. 1 depicts a single layer of light transmitting semiconductor material 7 of either the N or P type, in which light transmitting particles are embedded in the semiconductor material by the method described below. Light transmitting particles 8 are mixed with the semiconductor material 9 to form a light transmitting semiconductor material of either the N or P type. Light incident upon the single layer of light transmitting semiconductor material 7 comprises light absorbed 19 by the single layer 7, and light transmitted 18 through the single layer 7, which may be absorbed by N-P junctions below.

A first embodiment of the present invention is shown schematically in FIG. 2. A single junction photovoltaic cell 5 is comprised of a single layer of light transmitting N-type semiconductor material 1 brought into physical contact with a single layer of light transmitting P-type semiconductor material 2, forming an N-P junction 3 with light transmissive properties. The semiconductor materials are selected such that the N-P junction 3 generates an electric current in the presence of light. The P-type material 2 is comprised of a P-type semiconductor material with light transmitting materials interdispersed in the semiconductor material, and the N-type material 1 is comprised of an N-type semiconductor material with light transmitting materials interdispersed in the semiconductor material. Light incident upon the photovoltaic cell comprises light absorbed 6 by the first N-P junction, and light transmitted 4 through the semiconductor materials to be absorbed by N-P junctions that may be disposed below the first N-P junction. An embodiment of the single junction photovoltaic cell within the scope of the present invention may comprise a single layer of light transmitting P-type semiconductor material being disposed in direct vertical alignment below a single layer of light transmitting N-type semiconductor material.

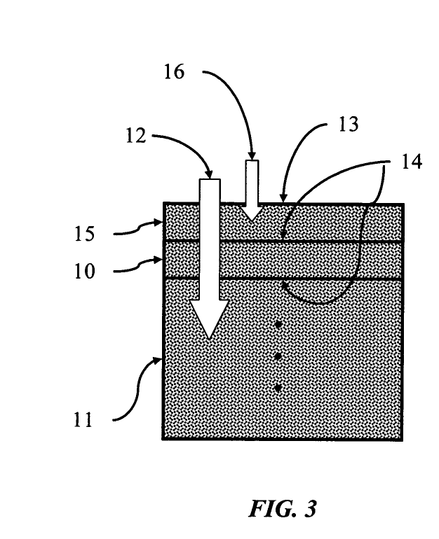

A second embodiment of the current invention is shown schematically in FIG. 3. A multi-junction photovoltaic cell 13 is comprised of a plurality of layers of light transmitting N-type semiconductor layers 15 and a plurality of light transmitting P-type semiconductor layers 10 brought together in alternating fashion and in physical contact with one another to form a plurality of layers of N-P junctions 14, in which the semiconductor materials are selected such that the N-P junctions generate an electric current in the presence of light. The resulting structure is a stacked multi-layer photovoltaic cell 13 comprising a plurality of N-P junctions 14 formed by alternating types of light transmitting semiconductor layers in physical contact with one another. Light incident upon the photovoltaic cell comprises light absorbed 16 by the first layer of light transmitting semiconductor material, and light transmitted 12 through the semiconductor layers to be absorbed by the semiconductors in the remaining layers 11. An electric current is generated by each N-P junction. Depending on the type of use, an embodiment of the multi-junction photovoltaic cell within the scope of the present invention may be comprised of a layer of light transmitting P-type semiconductor material being disposed below a topmost layer of light transmitting N-type semiconductor material within the multi-junction photovoltaic cell. The present invention encompasses an interchangeability in the starting layer and the thereafter alternating P-type layers and N-type layers within the multi-layer photovoltaic cell.

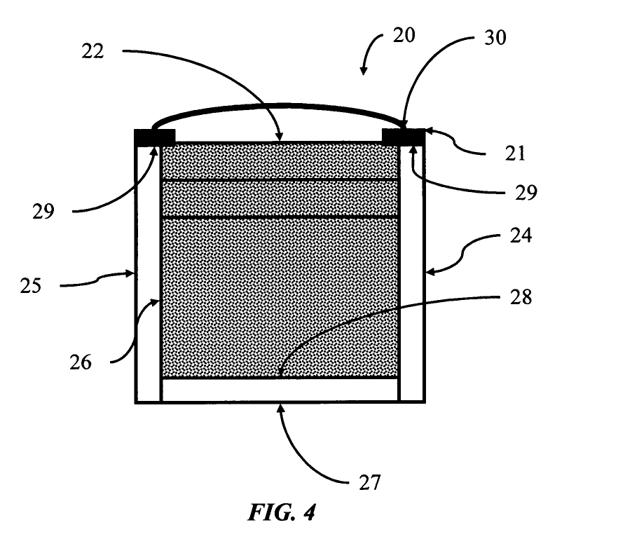

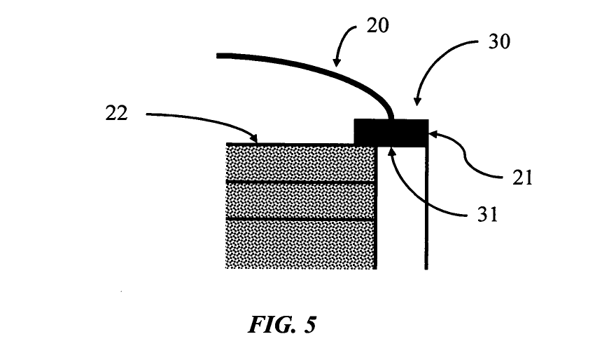

A third embodiment of the current invention is shown schematically in FIG. 4. A photovoltaic cell, as described above and which may be of the single or multi-layer type, but optimally is of the multi-layer type, is packaged for use and is housed inside an enclosure. The enclosure comprises a sleeve 24 having an inner surface 26, an outer surface 25, and a top surface 29, said sleeve 24 being made of a material that is of the class of electrical non-conductors, and optimally is ceramic. The sleeve may be of any cross section including, but not limited to, round, square, rectangular, and the like. A plurality of light transmitting semiconductor layers are sequentially placed within the sleeve in alternating N-P fashion, forming at least one N-P junction to create a photovoltaic cell, this stacked photovoltaic cell having a first surface 22, a side surface and a bottom surface 28. The enclosure further comprises a bottom element 27 that is in circumferential contact with the inner surface 26 of the sleeve and in direct contact with the bottom surface 28 of the photovoltaic cell, said bottom element 27 being made of a material that is electrically conductive. The enclosure still further comprises an electrically conductive ring element 21 having cross section as shown in FIG. 5 and having a top surface 30 and a bottom surface 31. Bottom surface 31 of the ring element 21 is located in physical contact with the first surface 22 of the photovoltaic cell and with said top surface 29 of the sleeve 24 as shown in FIG. 4 and FIG. 5. The contact between the electrically conductive ring element 21 and the first surface 22 of the photovoltaic cell serves to draw current off. The enclosure yet further comprises a lens element 20 attached to the top surface 30 of the retaining ring element 21 by chemical bonding means such that the bottom surface 31 of ring element 21 remains in physical contact with the first surface 22 of the photovoltaic cell as shown in FIG. 4. The lens element 20 may be comprised of any of the class of materials transmissive to light including, but not limited to, clear plastic, glass, crystal or any other flight transmissive material, and may be a fresnel lens, a shaped lens such as a convex lens, a tall lens, a flat lens, or a collimating lens. When lens element 20 is a collimating lens, lens element 20 provides the beneficial capability of drawing more light into the orifice than if a flat lens had been used.

An alternative embodiment to the third embodiment described above, and depicted in FIG. 4, includes a bottom element 27 that is comprised of a material of the class of materials known as electrical conductors, said bottom element 27 being electrically bonded to the bottom surface 28 of the photovoltaic cell, thus forming an electrical contact with said bottom surface 28 of the photovoltaic cell. The electrical bonding means providing the electrical bond between the bottom element 27 and the bottom surface 28 of the photovoltaic cell may be any means of achieving an electrical bond including, but not limited to, heating of the semiconductor material via application of a radio frequency to the semiconductor material. Such an application of radio frequency melts the semiconductor material, thus creating a thin film.

The third embodiment and the alternative embodiments thereto may be used in any combination. The preferred embodiment is the combination shown in FIG. 4 in which the retaining ring 21 is comprised of electrically conductive material and the bottom element 27 is comprised of electrically conductive material. This particular preferred embodiment is comprised of a photovoltaic cell, comprising a plurality of N-P junctions which are comprised of light transmitting N and P semiconductor materials, housed within an enclosure comprising a non-conductive sleeve 24; an electrically conductive retaining ring 21; an electrically conductive bottom element 27; and a lens element 20. Said bottom surface 31 of retaining ring 21 and bottom element 27 provide a means for achieving an electrically conductive connection to the first surface 22 of the photovoltaic cell and the bottom surface 28 of the photovoltaic cell, respectively. Lens element 20, preferably an optically transmissive collimating lens, may be chemically bonded to the top surface of the ring element 21. The resulting embodiment is suitable for use in a variety of photovoltaic cell applications and may be constructed in a large variety of form factors and number of N-P junctions in order to meet specific voltage, current, and form factors requirements.

The invention is also directed to a means for transmitting light to all the layers of a multi-layer photovoltaic cell comprised of a first layer of semiconductor of either the N or P type, a second layer of semiconductor material of type opposing that of the first layer physically located underneath the first layer and in physical contact therewith, and successive alternating layers of semiconductor materials of either the N type or the P type physically located underneath the second layer, in which the N type materials are comprised of an N-type semiconductor material with light transmitting materials interdispersed in the semiconductor material, and P-type materials are comprised of an P-type semiconductor material with light transmitting materials interdispersed in the semiconductor material (see FIG. 3).

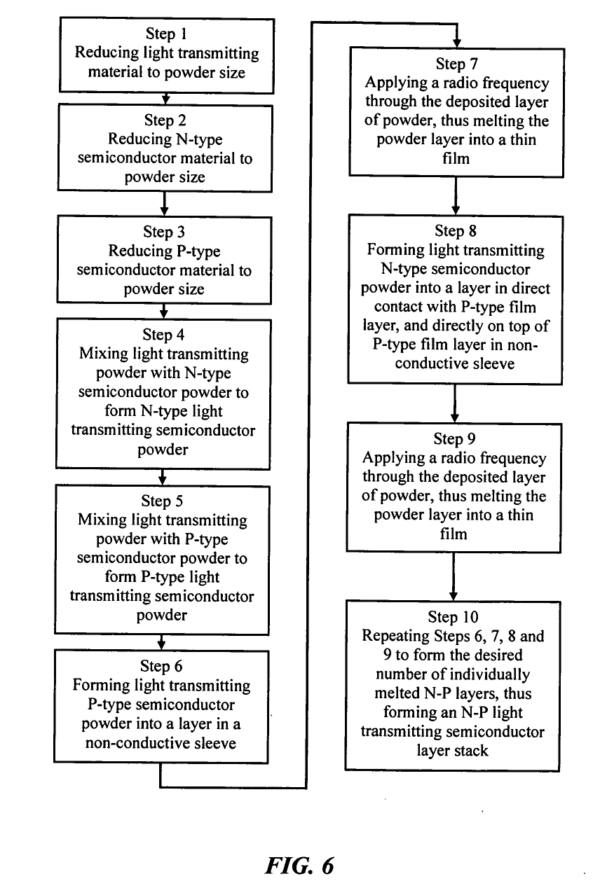

The invention is also directed to a method of interdispersing light transmitting material in the semiconductor layers of single or multi-junction photovoltaic cells as shown in FIG. 6. The method of FIG. 6 comprising of the steps of reducing the light transmitting material to a powder size, first by grinding to a particle size of 5 micrometers 150 micrometers, followed by further reducing the particles to a size between 400 nanometers and 800 nanometers, but optimally 700 nanometers, by wet ball milling; reducing an N-type semiconductor material to a powder size, first by grinding to a particle size of 5 micrometers to 150 micrometers, followed by further reducing the particles to a size between 400 nanometers and 800 nanometers, but optimally 700 nanometers, by wet ball milling; reducing a P-type semiconductor material to a powder size, first by grinding to a particle size of 5 micrometers to 150 micrometers, followed by further reducing the particles to a size between 400 nanometers and 800 nanometers, but optimally 700 nanometers, by wet ball milling; mixing the light transmitting powder with the N-type semiconductor powder to form an N-type light transmitting semiconductor mixture in powder form, mixing the reduced light transmitting powder with the reduced P-type semiconductor powder to form a P-type light transmitting semiconductor mixture in powder form, forming a layer of P-type light-transmitting semiconductor powder, forming a layer of N-type semiconductor powder directly on top of said P-type layer, repeating the steps of forming alternating P-type and N-type semiconductor powder layers to form a plurality of N-P semiconductor powder layers thus forming an N-P semiconductor layer stack, and forming a photovoltaic cell with light transmitting properties.

The forming of the photovoltaic cell may involve the successive application of a radio frequency to the layer stack, wherein the applied radio frequency flows through each layer, respectively, causing an increase in temperature and melting each layer of powder into a thin film. This radio frequency may be applied repeatedly layer by layer as each new layer of light transmitting semiconductor material is deposited. In this manner, a photovoltaic cell is fabricated that is comprised of a plurality of layers of light transmitting semiconductor materials in which each layer utilizes differing or similar light transmitting materials, in which the layers of light transmitting semiconductor materials are physically arranged within the photovoltaic cell in alternating P-type/N-type fashion, forming a plurality of N-P junctions that produce an electrical current in the presence of light.

The preferred method embodiment for fabricating multi-layer photovoltaic cells with integral light transmitting materials acting as light waveguides comprises the steps of reducing the light transmitting materials to a powder form, typically through grinding the light transmitting material to a size of 5 micrometers to 150 micrometers followed by further reducing the particle size to 400 nanometers to 800 nanometers, but optimally 700 nanometers, by wet ball milling; reducing a bulk P-type semiconductor material to a powder form, typically through grinding the material to a size of 5 micrometers to 150 micrometers followed by further reducing the particle size to 400 nanometers to 800 nanometers, but optimally 700 nanometers, by wet ball milling; reducing a bulk N-type semiconductor material to a powder form by first grinding the material to reduce it to particles between 5 micrometers and 150 micrometers in size followed by ball milling to further reduce the particles to between 400 nanometers and 800 hundred nanometers in size, but optimally 700 nanometers; mixing the light transmitting material powder into both the P-type and N-type semiconductor powder, respectively, in equal parts, or larger or smaller by volume; forming a first layer of light transmitting semiconductor powder comprising P-type semiconductor material, the first layer having a top and a bottom surface; applying a radio frequency to the newly formed first layer of light transmitting semiconductor powder, wherein application of the radio frequency melts the first layer into a thin film; forming a second layer of light transmitting semiconductor powder comprising N-type semiconductor material, the second layer having a top and a bottom surface and the second layer being in direct physical and electrical contact with the top surface of the first layer and further in direct vertical alignment therewith forming a first N-P junction, the junction having a top surface and a bottom surface; applying a radio frequency to the newly formed second layer of light transmitting semiconductor powder, wherein application of the radio frequency melts the second layer into a thin film; and repeating the above formation and application steps to provide a plurality of alternating layers of the N-type and P-type light transmitting semiconductor materials forming a plurality of N-P junctions. A radio frequency may be applied after each layer of light transmitting semiconductor powder is deposited, wherein the radio frequency melts the newly deposited light transmitting semiconductor powder layer into a film of between 500 to 600 nanometers. Another embodiment of the above method comprises the steps of forming a first layer and forming a second layer, respectively, further comprising the first and second layers being formed in an enclosure, the enclosure comprising a non-conductive sleeve, the sleeve preferably being ceramic; a conductive bottom element; a top conductive ring element; and a optically transmissive lens element, such as a collimating lens, that is bonded to a top surface of the ring element.

For all embodiments of the invention, it is not necessary that each successive layer of light transmitting semiconductor material utilize similar light transmitting materials. The light transmitting materials of the present invention are materials suitable for use in semiconductor manufacturing processes, able to retain light transmitting properties through, optimally, the application of radio frequency in the formation of the light transmitting semiconductor materials and junctions, and suitable for reduction to particle size for interdispersing within N-type and P-type semiconductors such as those used in photovoltaic cells. The light transmitting materials include crystals selected from the group consisting of optical calcite, tumbled clear or colored quartz, clear ulexite, clear Herkimer diamond, diamond, danburite, calcite, dolomite, scolecite, kunzite, crystallite, ruby, sapphire, glass, and man-made crystal materials that are transparent to light energy of the frequencies that will photo-generate an electrical potential in the cell. It is an aspect of the invention that any light transmitting material suitable for use in the photovoltaic cell manufacturing process is included within the scope of this disclosure, without regard to any specific index of transmissivity or refraction.

The semiconductor materials of the present invention are selected from the group of semiconductors known by those skilled in the art to be utilized in photovoltaic cell fabrication including but not limited to Se, Si, TiO₂, Ru, Ga, As, Ni, Te, Cd, S, C, In, Pt, a-Si, Al, B, Sb, Be, Ca, Cr, Au, I, Ir, Li, Mg, Mo, Pd, P, K, Rh, Cu, Ag, Na, Ta, Sn, Zn, Ge, GaAs, GaNi, CdTe, CdS, and CdSe, but optimally is CdTe/CdS. Some semiconductors may be doped to be either P-type or N-type semiconductors. It is an aspect of the invention that there is no upper limit upon the number of N-P layers utilized to form the multi-junction photovoltaic cell.

While certain preferred and alternate embodiments of the invention are described, those embodiments are presented by way of example only and are not intended to limit the scope and breadth of disclosure of the invention. Various modifications and alternate embodiments may occur to those skilled in the art without departing from the spirit, gist, and scope of the invention as defined in the disclosure and in the claims.

What is claimed is:

1. A photovoltaic cell having at least two semiconductor layers, said photovoltaic cell comprising:
a first semiconductor layer, said first layer comprising N type semiconductor material having a top surface and a bottom surface, wherein light transmitting particles are interdispersed within said N type semiconductor material; and
a second semiconductor layer, said second layer comprising P type semiconductor material having a top surface and a bottom surface, wherein light transmitting particles are interdispersed within said P type semiconductor material, said top surface of said second layer being in direct physical and electrical contact with said bottom surface of said first layer to form an N-P junction.

2. The photovoltaic cell of claim 1, wherein said photovoltaic cell further comprises a first surface, a bottom surface and a plurality of N-P junctions.

3. The photovoltaic cell of claim 2, wherein said photovoltaic cell is disposed within an enclosure, said enclosure comprising:
a conductive bottom element having a top surface, a bottom surface, and a side surface, said top surface of said bottom element in direct physical and electrical contact with said bottom surface of said photovoltaic cell; and
a non-conductive sleeve having an inner surface, an outer surface, a top surface, and a bottom surface, said sleeve enclosing said photovoltaic cell and enclosing said side surface of said bottom element, said sleeve extending from said bottom surface of said bottom element to said first surface of said photovoltaic cell.

4. The photovoltaic cell of claim 3, wherein said enclosure further comprises:
an electrically conductive ring element having a top surface and a bottom surface, said ring element extending to said outer surface of said sleeve, said bottom surface of said ring element in physical contact with both said top surface of said sleeve and said first surface of said photovoltaic cell; and
a lens element having a bottom surface, said bottom surface of said lens element in physical contact with and bonded to said top surface of said conductive ring

5. The photovoltaic cell of claim 4, wherein said sleeve is ceramic.

6. The photovoltaic cell of claim 5, wherein said lens element is a collimating lens.

7. The photovoltaic cell of claim 5, wherein said lens element is selected from the group consisting a fresnel lens, a shaped lens such as a convex lens, a tall lens, a flat lens, or a collimating lens.

8. A method of interdispersing light transmitting particles into a semiconductor material to form a light transmitting semiconductor powder, comprising:
acquiring a bulk light transmitting crystal material;
reducing said bulk light transmitting material into light transmitting particles of between 5 micrometers and 150 micrometers in size,
further reducing said light transmitting particles to between 400 and 800 nanometers in size to form a light transmitting powder;
acquiring bulk semiconductor material;
reducing said bulk semiconductor material into semiconductor particles of between 5 micrometers and 150 micrometers in size,
further reducing said semiconductor particles to between 400 and 800 nanometers in size to form a semiconductor powder; and
mixing said light transmitting powder with said semiconductor powder.

9. The method of interdispersing light transmitting particles into a semiconductor material of claim 8, wherein said mixing said light transmitting powder with said semiconductor powder, respectively, occurs in a ratio by volume selected from the group consisting of an equal ratio by volume, a larger ratio by volume, and a smaller ratio by volume.

10. The method of interdispersing light transmitting particles into a semiconductor material of claim 9, wherein said acquiring a bulk light transmitting crystal material comprises selecting said bulk light transmitting crystal material from the group consisting of optical calcite, tumbled clear quartz, colored quartz, clear ulexite, clear Herkimer diamond, diamond, danburite, calcite, dolomite, scolecite, kunzite, crystallite, glass, and man-made crystal materials that are transparent to light energy of the frequencies usable by photovoltaic cells for the purpose of generating electric current.

11. The method of interdispersing light transmitting particles into a semiconductor material of claim 10, wherein said acquiring bulk semiconductor material comprises selecting said bulk semiconductor material from the group consisting of Se, Si, a-Si, TiO₂, Ru, Ga, As, Ni, Te, Cd, S, C, In, Pt, Cu, Al, B, Sb, Be, Ca, Cr, Au, I, Ir, Li, Mg, Mo, Pd, P, K, Rh, Ag, Na, Ta, Sn, Zn, Ge, GaAs, GaNi, CdS, CdSe and CdTe.

12. A method of fabricating a photovoltaic cell with light transmitting properties, comprising:
providing a light-transmitting semiconductor powder comprising N-type semiconductor material;
providing a light transmitting semiconductor powder comprising P-type semiconductor material;
forming a first layer of light transmitting semiconductor powder comprising P-type semiconductor material, said first layer having a top surface and a bottom surface;
applying a radio frequency to newly formed said first layer of light transmitting semiconductor powder, wherein said application of said radio frequency melts said first layer into a thin film;
forming a second layer of light transmitting semiconductor powder comprising N-type semiconductor material, said second layer having a top surface, a bottom surface, and being in direct physical and electrical contact with said top surface of said first layer of light transmitting semiconductor powder, said first layer and said second layer being in direct vertical alignment therewith to form a first N-P junction, said junction having a top surface and a bottom surface; and
applying a radio frequency to said second layer of light transmitting semiconductor powder, wherein said application of said radio frequency melts said second layer into a thin film.

13. The method of fabricating a photovoltaic cell with light transmitting properties of claim 12, wherein said formation and said application steps are repeated at least once, forming a plurality of said N-P junctions.

14. The method of fabricating a photovoltaic cell with light transmitting properties of claim 13, wherein said photovoltaic cell is formed within an enclosure comprising:
a conductive bottom element having a top surface, a bottom surface, and a side surface, said top surface of said bottom element in physical and electrical contact with said bottom surface of said plurality of N-P junctions; and
a non-conductive sleeve having an inner surface, an outer surface, a top surface, and a bottom surface, said sleeve enclosing said side surface of said plurality of N-P junctions and enclosing said side surface of said bottom element, said sleeve extending from said bottom surface of said bottom element to said top surface of said plurality of N-P junctions.

15. The method of fabricating a photovoltaic cell with light transmitting properties of claim 14, wherein said enclosure further comprises:
an electrically conductive ring element having a top surface and a bottom surface, said ring element extending to said outer surface of said sleeve, said bottom surface of said ring element in physical contact with both said top surface of said sleeve and said top surface of said plurality of N-P junctions; and
a lens element having a bottom surface, said bottom surface of said lens element in physical contact with and bonded to said top surface of said conductive ring element.

16. The method of fabricating a photovoltaic cell with light transmitting properties of claim 15, wherein said applying a radio frequency to newly formed said layer of light transmitting semiconductor powder further comprises applying one polarity of voltage to said top surface thereof and the other polarity to said bottom surface thereof.

17. The method of fabricating a photovoltaic cell with light transmitting properties of claim 16, wherein said non-conductive sleeve is ceramic.

18. The method of fabricating a photovoltaic cell with light transmitting properties of claim 17, wherein said lens element is a collimating lens.

19. The method of fabricating a photovoltaic cell with light transmitting properties of claim 17, wherein said lens element is selected from the group consisting a fresnel lens, a shaped lens such as a convex lens, a tall lens, a flat lens, or a collimating lens.
